(19) United States
(12) Patent Application Publication
(10) Pub. No.: US 2022/0169956 A1
(43) Pub. Date: Jun. 2, 2022

(54) COMPOSITION COMPRISING AN AMMONIA-ACTIVATED SILOXANE FOR AVOIDING PATTERN COLLAPSE WHEN TREATING PATTERNED MATERIALS WITH LINE-SPACE DIMENSIONS OF 50 NM OR BELOW

(71) Applicant: BASF SE, Ludwigshafen am Rhein (DE)

(72) Inventors: Chi Yueh Kao, Taoyuan (TW); Mei Chin Shen, Taoyuan (TW); Sheng Hsuan Wei, Taoyuan (TW); Daniel Loeffler, Ludwigshafen (DE); Andreas Klipp, Ludwigshafen (DE); Marcel Brill, Ludwigshafen (DE); Szilard Csihony, Ludwigshafen (DE); Frank Pirrung, Ludwigshafen (DE); Niklas Benjamin Heine, Ludwigshafen (DE)

(21) Appl. No.: 17/601,740

(22) PCT Filed: Mar. 27, 2020
(86) PCT No.: PCT/EP2020/058699

§ 371 Date: Oct. 6, 2021

(30) Foreign Application Priority Data
Apr. 9, 2019 (DE) 19168153.5

(51) Int. Cl. C11D 7/26; G03F 7/40; C11D 11/00; C11D 7/50; C11D 7/24; C11D 7/02

(52) U.S. Cl. CPC C11D 7/26; G03F 7/405; C11D 7/02; C11D 7/5022; C11D 7/241; C11D 11/0047

(57) ABSTRACT

Described herein is a non-aqueous composition including (a) an organic protic solvent, (b) ammonia, and (c) at least one additive of formulae I or II

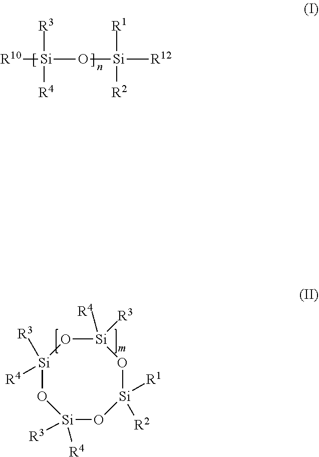

where
R¹ is H
R² is selected from H, C₁ to C₁₀ alkyl, C₁ to C₁₀ alkoxy, C₆ to C₁₀ aryl, and C₆ to C₁₀ aroxy,
R³ is selected from R²,
R⁴ is selected from C₁ to C₁₀ alkyl, C₁ to C₁₀ alkoxy, C₆ to C₁₀ aryl, and C₆ to C₁₀ aroxy,
R¹⁰, R¹² are independently selected from C₁ to C₁₀ alkyl and C₁ to C₁₀ alkoxy,
m is 1, 2 or 3, and
n is 0 or an integer from 1 to 100.

Composition comprising an ammonia-activated siloxane for avoiding pattern collapse when treating patterned materials with line-space dimensions of 50 nm or below.

The present invention is directed to a composition for anti-pattern-collapse treatment, its use for and a process for manufacturing integrated circuits devices, optical devices, micromachines and mechanical precision devices.

### BACKGROUND OF THE INVENTION

In the process of manufacturing ICs with LSI, VLSI and ULSI, patterned material layers like patterned photoresist layers, patterned barrier material layers containing or consisting of titanium nitride, tantalum or tantalum nitride, patterned multi-stack material layers containing or consisting of stacks e.g. of alternating polysilicon and silicon dioxide or silicon nitride layers, and patterned dielectric material layers containing or consisting of silicon dioxide or low-k or ultra-low-k dielectric materials are produced by photolithographic techniques. Nowadays, such patterned material layers comprise structures of dimensions even below 22 nm with high aspect ratios.

Irrespective of the exposure techniques the wet chemical processing of small patterns however involves a plurality of problems. As technologies advance and dimension requirements become stricter and stricter, patterns are required to include relatively thin and tall structures or features of device structures i.e., features having a high aspect ratio, on the substrate. These structures may suffer from bending and/or collapsing, in particular, during the spin dry process, due to excessive capillary forces of the liquid or solution of the rinsing liquid deionized water remaining from the chemical rinse and spin dry processes and being disposed between adjacent patterned structures.

Due to the shrinkage of the dimensions, the removal of particles and plasma etch residues in order to achieve a defect free patterned structure becomes also a critical factor. This does apply to photoresist patterns but also to other patterned material layers, which are generated during the manufacture of optical devices, micromachines and mechanical precision devices.

WO 2012/027667 A2 discloses a method of modifying a surface of a high aspect ratio feature by contacting the surface of the high aspect ratio feature with an additive composition to produce a modified surface, wherein forces acting on the high aspect ratio feature when a rinse solution is in contact with the modified surface are sufficiently minimized to prevent bending or collapse of the high aspect ratio feature at least during removal of the rinse solution or at least during drying of the high aspect ratio feature. The modified surface should have a contact angle in a range from about 70 degrees to about 110 degrees. Besides many other types of acids, bases, non-ionic surfactants, anionic surfactants, cationic surfactants, and zwitterionic surfactants, some siloxane-type surfactants are disclosed. A variety of solvents, including ethylene glycol, isopropanol, 1-methoxy-2-propyl acetate, isopropyl acetate, ethyl carbonate dimethyl sulfoxide and hexane are described.

WO 2014/091363 A1 discloses a water-based composition comprising a hydrophobizer in combination with a surfactant having a surface tension of 10 mN/m to 35 mN/m, which, besides other types of surfactants, may be a siloxane-type surfactant. The water-based composition is preferably free of organic solvents.

WO2019/086374 discloses a water based anti-pattern collapse solution comprising a siloxane-type additive.

US 2018/0254182 discloses the use of silanes like hexamethyl disilazane in compositions for surface treatment that is capable of highly hydrophobizing (silylating) a surface of a treatment target while deterioration of polyvinyl chloride is suppressed when surface treatment of the treatment target such as an inorganic pattern and a resin pattern is carried out using a device having a liquid contact portion provided with a member made of polyvinyl chloride.

However, these compositions still suffer from high pattern collapse in sub 50 nm structures.

It is an object of the present invention to provide a method for manufacturing integrated circuits for nodes of 50 nm and lower, in particular for nodes of 32 nm and lower and, especially, for nodes of 22 nm and lower, which method no longer exhibits the disadvantages of prior art manufacturing methods.

In particular, the compounds according to the present invention shall allow for the chemical rinse of patterned material layers comprising patterns with a high aspect ratio and line-space dimensions of 50 nm and less, in particular, of 32 nm and less, especially, of 22 nm and less, without causing pattern collapse.

### SUMMARY OF THE INVENTION

The present invention completely avoids, all the disadvantages of the prior art by using a non-aqueous composition comprising an organic solvent in combination with a siloxane-type non-ionic additive as described herein.

A first embodiment of the present invention is a non-aqueous composition comprising
(a) an organic protic solvent
(b) ammonia, and
(c) at least one additive of formulae I or II

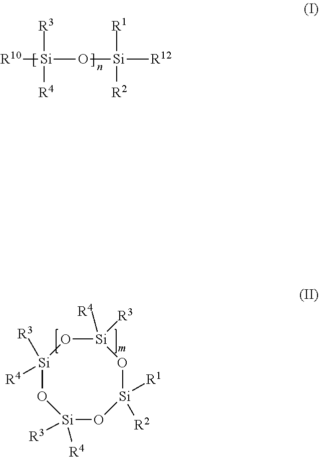

wherein
R¹ is H
R² is selected from H, C₁ to C₁₀ alkyl, C₁ to C₁₀ alkoxy, C₆ to C₁₀ aryl, and C₆ to C₁₀ aroxy,
R³ is selected from R²,
R⁴ is selected from C₁ to C₁₀ alkyl, C₁ to C₁₀ alkoxy, C₆ to C₁₀ aryl, and C₆ to C₁₀ aroxy,
R¹⁰, R¹² are independently selected from C₁ to C₁₀ alkyl and C₁ to C₁₀ alkoxy,
m is 1, 2 or 3,
n is 0 or an integer from 1 to 100.

Surprisingly it was found that the additives according to the invention comprising at least one H atom bound to an Si atom provide better pattern collapse rates when used for cleaning than fully-substituted ones.

Another embodiment of the present invention is a kit comprising (a) ammonia dissolved in an organic protic solvent, and (b) at least one additive of formulae I as defined herein.

Yet another embodiment of the present invention is the use of the compositions described herein for treating substrates having patterned material layers having line-space dimensions of 50 nm or below, aspect ratios of greater or equal 4, or a combination thereof.

Yet another embodiment of the present invention is a method for manufacturing integrated circuit devices, optical devices, micromachines and mechanical precision devices, the said method comprising the steps of
(1) providing a substrate having patterned material layers having line-space dimensions of 50 nm or below, aspect ratios of greater or equal 4, or a combination thereof,
(2) contacting the substrate at least once with a composition according to anyone of claims 1 to 10, and
(3) removing the non-aqueous composition from the contact with the substrate.

The compositions comprising an organic protic solvent, preferably an alcohol, in combination and an H-silane that has been activated by ammonia is particularly useful for anti-pattern-collapse treatment of substrates comprising patterns having line-space dimensions of 50 nm or less, particularly of 32 nm or less and, most particularly 22 nm or less. Furthermore, the compositions according to the invention is particularly useful for aspect ratios greater or equal 4 without causing pattern collapse. Last not least, due to the use of a protic organic solvent and optionally an alkane as solvent, the composition has an excellent compatibility with substrates comprising polyvinyl chloride.

It has to be noted that the cleaning or rinsing solutions comprising an organic polar solvent in combination with H-silane that was activated by ammonia are generally useful for avoiding pattern collapse of photoresist structures as well as of non-photoresist patterns with high aspect ratios stacks (HARS), particularly patterned multi-stack material layers containing or consisting of stacks comprising alternating polysilicon and silicon dioxide or silicon nitride layers.

### DETAILED DESCRIPTION OF THE INVENTION

The present invention is directed to a composition particularly suitable for manufacturing patterned materials comprising sub 50 nm sized features like integrated circuit (IC) devices, optical devices, micromachines and mechanical precision devices, in particular IC devices.

Any customary and known substrates used for manufacturing IC devices, optical devices, micromachines and mechanical precision devices can be used in the process of the invention. Preferably, the substrate is a semiconductor substrate, more preferably a silicon wafer, which wafers are customarily used for manufacturing IC devices, in particular IC devices comprising ICs having LSI, VLSI and ULSI.

The composition is particularly suitable for treating substrates having patterned material layers having line-space dimensions of 50 nm and less, in particular, 32 nm and less and, especially, 22 nm and less, i.e. patterned material layers for the sub-22 nm technology nodes. The patterned material layers preferably have aspect ratios above 4, preferably above 5, more preferably above 6, even more preferably above 8, even more preferably above 10, even more preferably above 12, even more preferably above 15, even more preferably above 20. The smaller the line-space dimensions and the higher the aspect ratios are the more advantageous is the use of the composition described herein.

The composition according to the present invention may be applied to substrates of any patterned material as long as structures tend to collapse due to their geometry.

By way of example, the patterned material layers may be
(a) patterned silicon oxide or silicon nitride coated Si layers,
(b) patterned barrier material layers containing or consisting of ruthenium, cobalt, titanium nitride, tantalum or tantalum nitride,
(c) patterned multi-stack material layers containing or consisting of layers of at least two different materials selected from the group consisting of silicon, polysilicon, silicon dioxide, SiGe, low-k and ultra-low-k materials, high-k materials, semiconductors other than silicon and polysilicon, and metals, and
d) patterned dielectric material layers containing or consisting of silicon dioxide or low-k or ultra-low-k dielectric materials.

Solvent

The non-aqueous anti-pattern-collapse composition comprises a polar protic organic solvent. Due to their hydrophilicity organic protic solvents are usually hygroscopicity and have a rather high amount of residual water unless removed by drying. Therefore, the organic protic solvents are preferably dried before its use in the anti-pattern-collapse compositions.

As used herein, “non-aqueous” means that the composition may only contain low amounts of water up to about 1% by weight. Preferably the non-aqueous composition comprises less than 0.5% by weight, more preferably less than 0.2% by weight, even more preferably less than 0.1% by weight, even more preferably less than 0.05% by weight, even more preferably less than 0.02% by weight, even more preferably less than 0.01% by weight, even more preferably less than 0.001% by weight of water. Most preferably essentially no water is present in the composition. “Essentially” here means that the water present in the composition does not have a significant influence on the performance of the additive in the non-aqueous solution with respect to pattern collapse of the substrates to be treated.

The organic solvents need to have a boiling point sufficiently low to be removed by heating without negatively impacting the substrate treated with the composition. For typical substrates, the boiling point of the organic solvent should be 150° C. or below, preferably 100° C. or below.

In a preferred embodiment the solvent essentially consists of one or more organic protic solvents, preferably a single polar protic organic solvent.

In another preferred embodiment the solvent essentially consists of one or more organic protic solvents and one or more non-polar C₅ to C₁₂ alkane solvents. Preferred are one or more alkane solvents, most preferred a single alkane solvent.

As used herein a “polar protic organic solvent” is an organic solvent which comprises an acidic hydrogen (i.e. that can donate a hydrogen ion).

Typical polar protic organic solvents are, without limitation, (a) C₁ to C₁₀ alcohols, (b) primary or secondary amines, carboxylic acids, such as but not limited to formic acid or acetic acid, or (c) primary or secondary amides, such as but not limited to formamide.

Preferred protic organic solvents are linear, branched or cyclic C₁ to C₁₀ aliphatic alkanols, particularly linear or branched C₁ to C₆ alkanols, which comprise at least one hydroxy group. Preferred alkanols are methanol, ethanol, 1-propanol, 2-propanol (isopropanol) or butanols. The most preferred alkanol is isopropanol.

Preferred C₅ to C₁₂ alkane solvents are selected from linear, branced or cyclic hexane, heptane, octane, nonane, and decane. Particularly preferred C₅ to C₁₂ alkane solvents are selected from linear or branched hexane, heptane, or octane. The most preferred C₅ to C₁₂ alkane solvent is linear or branched heptane, particularly linear heptane.

Additives of Formula I or II

In a first embodiment the non-ionic H-silane additive according to the present invention (also referred to as additive or more specifically silane or siloxane) may be selected from formula I or II:

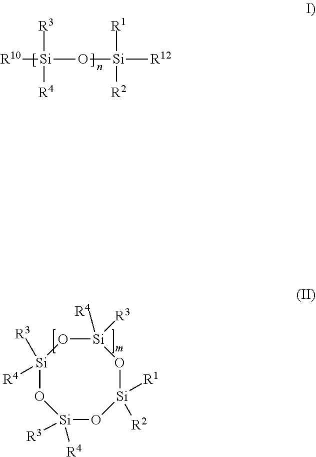

Herein R¹ is H, i.e. the additive according to the invention is an H-silane or H-siloxane. The H-silane or H-siloxane show a much better performance compared to other silanes or siloxanes like tetraethyl orthosilicate.

In formula I and II R² may be selected from H, C₁ to C₁₀ alkyl, C₁ to C₁₀ alkoxy, C₆ to C₁₂ aryl, and C₆ to C₁₀ aroxy. Preferably R² may be selected from C₁ to C₈ alkyl, C₁ to C₈ alkoxy. More preferably R² may be selected from C₁ to C₆ alkyl and C₁ to C₆ alkoxy. Most preferably R² may be selected from C₁ to C₄ alkyl and C₁ to C₄ alkoxy. Most preferred groups R² may be selected from methyl, ethyl, methoxy and ethoxy.

R³ may be selected from H, C₁ to C₁₀ alkyl, C₁ to C₁₀ alkoxy, C₆ to C₁₀ aryl, and C₆ to C₁₀ aroxy. Preferably R³ may be selected from H, C₁ to C₈ alkyl, C₁ to C₈ alkoxy. More preferably R³ may be selected from H, C₁ to C₆ alkyl and C₁ to C₆ alkoxy. Even more preferably R³ may be selected from H, C₁ to C₄ alkyl and C₁ to C₄ alkoxy. Most preferred groups R³ may be selected from H, methyl, ethyl, methoxy and ethoxy.

R⁴ may be selected from C₁ to C₁₀ alkyl, C₁ to C₁₀ alkoxy, C₆ to C₁₀ aryl, and C₆ to C₁₀ aroxy. Preferably R⁴ may be selected from C₁ to C₈ alkyl, C₁ to C₈ alkoxy. More preferably R⁴ may be selected from C₁ to C₆ alkyl and C₁ to C₆ alkoxy. Most preferably R⁴ may be selected from C₁ to C₄ alkyl and C₁ to C₄ alkoxy. Most preferred groups R⁴ may be selected from methyl, ethyl, methoxy and ethoxy.

R¹⁰, R¹² may be independently selected from C₁ to C₁₀ alkyl and C₁ to C₁₀ alkoxy. Preferably R¹⁰, R¹² and R⁴ may be selected from C₁ to C₈ alkyl, C₁ to C₈ alkoxy. More preferably R¹⁰ and R¹² may be selected from C₁ to C₆ alkyl and C₁ to C₆ alkoxy. Most preferably R¹⁰ and R¹² may be selected from C₁ to C₄ alkyl and C₁ to C₄ alkoxy. Most preferred groups R⁴ may be selected from methyl, ethyl, methoxy and ethoxy.

In formula I n may be 0 or an integer from 1 to 100, preferably 0, or an integer from 1 to 50, even more preferably 0 or an integer from 1 to 20, most preferably 0. In formula II m may be 1, 2 or 3, preferably 1.

Preferably R², R⁴, R¹⁰, and R¹² are independently selected from methyl, methoxy, ethyl, ethoxy, propyl, and propoxy.

In a particular preferred embodiment the additive is selected from trimethoxysilane, triethoxysilane, trimethylsilane, and triethylsilane.

The concentration should be sufficiently high to properly prevent pattern collapse but should be as low as possible for economic reasons. The concentration of the additives of formula I or II in the non-aqueous solution may generally be in the range of about 0.00005 to about 15% by weight. Preferably the concentration of the additive if from about 0.001 to about 12% by weight, more preferably from about 0.005 to about 12% by weight, even more preferably from about 0.05 to about 10% by weight, and most preferably 0.1 to 5% by weight, the weight percentages being based on the overall weight of the composition.

There may be one or more additives in the composition, however it is preferred to use only one additive of formula I or II.

Ammonia Activation

It is required to activate the H-silane additive described above by adding ammonia. Such activation is generally possible by adding from about 0.05 to about 8% by weight of ammonia to the solution. Below 0.05% by weight the activation is insufficient, using more than about 8% by weight is difficult to achieve due to limited solubility of ammonia in the protic organic solvent. Preferably 0.2 to 6% by weight, more preferably from 0.3 to 4% by weight, most preferably 0.5 to 2% by weight are used for the activation.

Further Additives

Further additive may be present in the cleaning solution according to the present invention. Such additives may be
(I) buffer components for pH adjustment such as but not limited to (NH₄)₂CO₃/NH₄OH, Na₂CO₃/NaHCO₃, tris-hydroxymethyl-aminomethane/HCl, Na₂HPO₄/NaH₂PO₄, or organic acids like acetic acid etc., methanesulfonic acid,
(II) one or more further additives, either non-ionic, or, anionic to improve surface tension and solubility of the mixture, or
(III) dispersants to prevent the surface re-attachment of the removed particles of dirt or polymer.

Rinsing Solution

Preferably the non-aqueous composition consists essentially of the organic protic solvent, optionally a C₅ to C₁₂ alkane, the at least one additive of formula I or II, ammonia, and reaction products thereof.

Preferably the ammonia is added in situ just before its use. Therefore, it is advantageous to supply the compositions as a two-component kit comprising (a) ammonia dissolved in the organic protic solvent and optionally a C₅ to C₁₂ alkane, and (b) at least one additive of formulae I or II as described herein.

Application

The compositions described herein may be used for treating substrates having patterned material layers having line-space dimensions of 50 nm or below, aspect ratios of greater or equal 4, or a combination thereof.

The compositions described herein may be used in a method for manufacturing integrated circuit devices, optical devices, micromachines and mechanical precision devices has been found, the method comprising the steps of
(1) providing a substrate having patterned material layers having line-space dimensions of 50 nm and less and aspect ratios of greater or equal 4,
(2) contacting the substrate at least once with a non-aqueous, solution containing at least a siloxane additive as described herein, and
(3) removing the aqueous solution from the contact with the substrate.

Preferably the substrate is provided by a photolithographic process comprising the steps of
(i) providing the substrate with an immersion photoresist, EUV photoresist or eBeam photoresist layer,
(ii) exposing the photoresist layer to actinic radiation through a mask with or without an immersion liquid,
(iii) developing the exposed photoresist layer with a developer solution to obtain a pattern having line-space dimensions of 32 nm and less and an aspect ratio of 10 or more,
(iv) applying the non-aqueous composition described herein to the developed patterned photoresist layer, and
(v) spin drying the semiconductor substrate after the application of the non-aqueous composition.

Any customary and known immersion photoresist, EUV photoresist or eBeam photoresist can be used. The immersion photoresist may already contain at least one of the siloxane additives or a combination thereof. Additionally, the immersion photoresist may contain other nonionic additives. Suitable nonionic additives are described, for example, in US 2008/0299487 A1, page 6, paragraph [0078]. Most preferably, the immersion photoresist is a positive resist.

Beside e-Beam exposure or extreme ultraviolet radiation of approx. 13.5 nm, preferably, UV radiation of the wavelength of 193 nm is used as the actinic radiation.

In case of immersion lithography preferably, ultra-pure water is used as the immersion liquid.

Any customary and known developer solution can be used for developing the exposed photoresist layer. Preferably, aqueous developer solutions containing tetramethylammonium hydroxide (TMAH) are used.

Preferably, the chemical rinse solutions are applied to the exposed and developed photoresist layers as puddles.

In the third step of the method the non-aqueous solution is removed from the contact with the substrate. Any known methods customarily used for removing liquids from solid surfaces can be employed.

It is essential for photolithographic process according to the method of the invention, that the chemical rinse solution contains at least one of the siloxane additives.

Customary and known equipment customarily used in the semiconductor industry can be used for carrying out the photolithographic process in accordance with the method of the invention.

### EXAMPLES

### Example 1

Patterned silicon wafers with a circular nano pillar pattern were used to determine the pattern collapse performance of the formulations during drying. The (aspect ratio) AR 20 pillars used for testing have a height of 600 nm and a diameter of 30 nm. The pitch size is 90 nm. 1×1 cm wafer pieces where processed in the following sequence without drying in between:
50 s Dilute Hydrofluoric Acid (DHF) 0.9% dip,
60 s ultra-pure water (UPVV) dip,
60 s isopropanol (IPA) dip,
60 s dip of a solution of the respective ammonia-activated additive in the solvent, either a protic organic solvent or a mixture of a protic and a non-polar organic solvent, at room temperature,
60 s IPA dip,
N₂ blow dry.

The additives were activated in-situ by adding the respective additives to a solution of 1% by weight of ammonia in the solvent. The water content of the solvent was below 0,01% by weight.

The compositions of table 1.1 were used in the examples.

TABLE 1

| | | Conc. | NH₃ | Protic | Conc. | Non-polar | Conc. |
|---|---|---|---|---|---|---|---|
| Example | Additive | [wt %] | [wt %] | Solvent | [wt %] | Solvent | [wt %] |
| Comp. 1.1 | n/a | 0 | 0 | isopropanol | 100 | n/a | 0 |
| 1.2 | triethoxysilane | 0.2 | 1 | isopropanol | 98.8 | n/a | 0 |
| 1.3 | triethoxysilane | 0.2 | 1 | isopropanol | 48.8 | heptane | 50 |
| 1.4 | triethoxysilane | 1 | 1 | isopropanol | 98 | n/a | 0 |
| 1.5 | triethoxysilane | 1 | 1 | isopropanol | 48 | heptane | 50 |
| 1.6 | triethoxysilane | 5 | 1 | isopropanol | 94 | n/a | 0 |
| 1.7 | triethoxysilane | 5 | 1 | isopropanol | 44 | n/a | 50 |
| 1.8 | triethoxysilane | 10 | 1 | isopropanol | 89 | n/a | 0 |
| 1.9 | triethoxysilane | 10 | 1 | isopropanol | 39 | heptane | 50 |

The dried silicon wafers where analyzed with top down SEM and the collapse statistics for examples 1.1 to 1.9 are shown in table 1.2.

The cluster size corresponds to number of uncollapsed pillars the respective cluster consist of. By way of example, if the wafer before treatment comprises 4×4 pillars and 8 remain uncollapsed, 4 collapse into two clusters comprising 2 pillars and 4 pillars collapse into one cluster comprising 4 pillars the ratio would be 8/11 single clusters, 2/11 double clusters and 1/11 clusters with four pillars.

TABLE 1.2

| | Uncollapsed |
|---|---|
| Example | structures [%] |
| Comp. 1.1 | 24.35 |
| 1.2 | 54.35 |
| 1.3 | 59.15 |
| 1.4 | 55.85 |
| 1.5 | 62.75 |
| 1.6 | 55.95 |
| 1.7 | 64.25 |
| 1.8 | 69.55 |
| 1.9 | 72.45 |

Table 1.2 shows that additives 1.1 to 1.9 have a beneficial effect on the degree of pattern collapse compared to the solution without any additive. The addition of an alkane further increases the ratio of uncollapsed structures.

### Example 2

Patterned silicon wafers with a circular nano pillar pattern were used to determine the pattern collapse performance of the formulations during drying. The (aspect ratio) AR 20 pillars used for testing have a height of 600 nm and a diameter of 30 nm. The pitch size is 90 nm. 1×1 cm wafer pieces where processed in the following sequence without drying in between:
40 sec SC1 dip (NH₄OH (28%)/H₂O₂ (31%)/ultra pure water (UPA) in a weight ratio of 1/8/60)
60 s ultra-pure water (UPVV) dip,
60 s isopropanol (IPA) dip,
60 s dip of a solution of the respective ammonia-activated additive in the solvent, either a protic organic solvent or a mixture of a protic and a non-polar organic solvent, at room temperature,
60 s IPA dip,
N₂ blow dry.

The additives were activated in-situ by adding the respective additives to a solution of 1% by weight of ammonia in the solvent. The water content of the solvent was below 0,01% by weight.

The compositions of table 2.1 were used in the examples.

TABLE 2.1

| | | Conc. | NH₃ | Protic | Conc. | Non-polar | Conc. |
|---|---|---|---|---|---|---|---|
| Example | Additive | [wt %] | [wt %] | Solvent | [wt %] | Solvent | [wt %] |
| Comp. 2.1 | n/a | 0 | 0 | isopropanol | 100 | n/a | 0 |
| 22 | triethoxysilane | 0.2 | 1 | isopropanol | 98.8 | n/a | 0 |
| 23 | triethoxysilane | 0.2 | 1 | isopropanol | 48.8 | heptane | 50 |
| 24 | triethoxysilane | 1 | 1 | isopropanol | 98 | n/a | 0 |
| 2.5 | triethoxysilane | 1 | 1 | isopropanol | 48 | heptane | 50 |
| 2.6 | triethoxysilane | 5 | 1 | isopropanol | 94 | n/a | 0 |
| 2.7 | triethoxysilane | 5 | 1 | isopropanol | 44 | n/a | 50 |
| 2.8 | triethoxysilane | 10 | 1 | isopropanol | 89 | n/a | 0 |
| 2.9 | triethoxysilane | 10 | 1 | isopropanol | 39 | heptane | 50 |

The dried silicon wafers where analyzed with top down SEM and the amount of uncollapsed structures for examples 2.1 to 2.9 are shown in table 2.2.

TABLE 2.2

| | Uncollapsed |
|---|---|
| Example | structures [%] |
| Comp. 2.1 | 0.35 |
| 2.2 | 22.15 |
| 2.3 | 59.3 |
| 2.4 | 50.7 |
| 2.5 | 70.1 |
| 2.6 | 82.25 |
| 2.7 | 88.7 |
| 2.8 | 89.65 |
| 2.9 | 92.7 |

The dried silicon wafers where analyzed with top down SEM.

Table 2.2 shows that the additives have a beneficial effect on the degree of pattern collapse compared to the solution without any additive.

### Example 3

Patterned silicon wafers with a circular nano pillar pattern were used to determine the pattern collapse performance of the formulations during drying. The (aspect ratio) AR 20 pillars used for testing have a height of 600 nm and a diameter of 30 nm. The pitch size is 90 nm. 1×1 cm wafer pieces where processed in the following sequence without drying in between:
50 s Dilute Hydrofluoric Acid (DHF) 0.9% dip,
60 s ultra-pure water (UPVV) dip,
60 s isopropanol (IPA) dip,
60 s dip of a solution of the respective ammonia-activated additive in the solvent, either a protic organic solvent or a mixture of a protic and a non-polar organic solvent, at room temperature,
60 s IPA dip,
N₂ blow dry.

The additives were activated in-situ by adding the respective additives to a solution of 1% by weight of ammonia in the solvent. The water content of the solvent was below 0,01% by weight.

The dried silicon wafers where analyzed with top down SEM and the collapse statistics for examples 3.1 to 3.4 are shown in table 1.

The compositions of table 3.1 were used in the examples.

TABLE 3.1

| | | Conc. | NH₃ | Protic | Conc. | Non-polar | Conc. |
|---|---|---|---|---|---|---|---|
| Example | Additive | [wt %] | [wt %] | Solvent | [wt %] | Solvent | [wt %] |
| Comp. 3.1 | n/a | 0 | 0 | isopropanol | 100 | n/a | 0 |
| 3.2 | 1 | 0.2 | 1 | isopropanol | 98.8 | n/a | 0 |
| 3.3 | 2 | 0.2 | 1 | isopropanol | 98.8 | n/a | 0 |
| 3.4 | 3 | 0.2 | 1 | isopropanol | 98.8 | n/a | 0 |

Additives 1, 2 and 3 have the following structures:

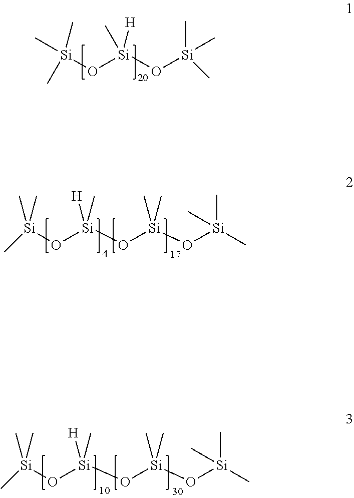

The dried silicon wafers where analyzed with top down SEM.

The pattern collapse Cluster Size Distribution was determined from the SEM images.

TABLE 3.2

| | Cluster Size Distribution | | | |
|---|---|---|---|---|
| | in collapsed structures [%] | | | |
| Example | 1 | 2 | 3-4 | > 5 |
| Comp. 3.1 | 49.9 | 35.3 | 14.6 | 0.2 |
| 3.2 | 59.6 | 27.2 | 12.6 | 0.6 |
| 3.3 | 77.6 | 18.2 | 4.1 | 0.2 |
| 3.4 | 75.8 | 17.1 | 6.7 | 0.4 |

Table 3.2 shows that additives have a beneficial effect on the degree of pattern collapse compared to the solution without any additive.

### Comparative Example 4

Patterned silicon wafers with a circular nano pillar pattern were used to determine the pattern collapse performance of the formulations during drying. The (aspect ratio) AR 20 pillars used for testing have a height of 600 nm and a diameter of 30 nm. The pitch size is 90 nm. 1×1 cm wafer pieces where processed in the following sequence without drying in between:
50 s Dilute Hydrofluoric Acid (DHF) 0.9% dip,
60 s ultra-pure water (UPVV) dip,
60 s isopropanol (IPA) dip,
60 s dip of a solution of the respective ammonia-activated additive in the solvent, either a protic organic solvent or a mixture of a protic and a non-polar organic solvent, at room temperature,
60 s IPA dip,
N₂ blow dry.

The additives were activated in-situ by adding the respective additives to a solution of 1% by weight of ammonia in the solvent. The water content of the solvent was below 0,01% by weight.

The compositions of table 4.1 were used in the examples.

TABLE 4.1

| | | Conc. | NH₃ | Protic | Conc. | Non-polar | Conc. |
|---|---|---|---|---|---|---|---|
| Example | Additive | [wt %] | [wt %] | Solvent | [wt %] | Solvent | [wt %] |
| Comp. 4.1 | — | 0 | 0 | isopropanol | 100 | n/a | 0 |
| Comp 4.2 | TEOS | 0.2 | 0 | isopropanol | 99.8 | n/a | 0 |
| Comp 4.3 | TEOS | 0.2 | 1 | isopropanol | 98.8 | n/a | 0 |

The dried silicon wafers where analyzed with top down SEM.

The pattern collapse Cluster Size Distribution was determined from the SEM images. The cluster size corresponds to number of uncollapsed pillars the respective cluster consist of. By way of example, if the wafer before treatment comprises 4×4 pillars and 8 remain uncollapsed, 4 collapse into two clusters comprising 2 pillars and 4 pillars collapse into one cluster comprising 4 pillars the ratio would be 8/11 single clusters, 2/11 double clusters and 1/11 clusters with four pillars.

The collapse statistics for examples 4.1 to 4.3 are shown in table 4.2.

TABLE 4.2

| | Cluster Size Distribution | | | |
|---|---|---|---|---|
| | in collapsed structures [%] | | | |
| Example | 1 | 2 | 3-4 | >5 |
| 1 | 81.4 | 16.8 | 1.8 | 0 |
| 2 | 19.5 | 3.7 | 76.2 | 0.6 |
| 3 | 80.8 | 17.1 | 2.1 | 0.1 |

Table 4.2 shows that non-H siloxanes like TEOS have no or less beneficial effect on the degree of pattern collapse compared to the solution without H siloxanes.

It is important to note that, due to the different pre-treatment and history of the respective wafers that were used, it is only possible to compare the results within one example, it is, however, not possible to compare results from different examples.

1. A non-aqueous composition comprising
(a) an organic protic solvent
(b) ammonia, and
(c) at least one additive of formulae I or II 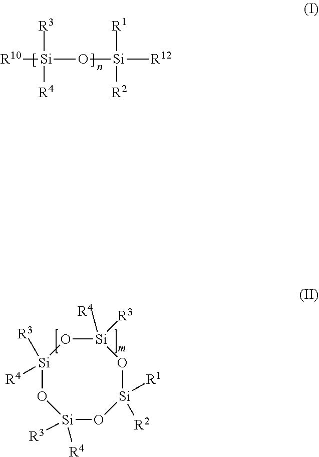
wherein
R¹ is H
R² is selected from the group consisting of H, C₁ to C₁₀ alkyl, C₁ to C₁₀ alkoxy, C₆ to C₁₀ aryl, and C₆ to C₁₀ aroxy,
R³ is selected from the group consisting of R²,
R⁴ is selected from the group consisting of C₁ to C₁₀ alkyl, C₁ to C₁₀ alkoxy, C₆ to C₁₀ aryl, and C₆ to C₁₀ aroxy,
R¹⁰, R¹² are independently selected from the group consisting of C₁ to C₁₀ alkyl and C₁ to C₁₀ alkoxy,
m is 1, 2 or 3, and
n is 0 or an integer from 1 to 100.

2. The composition according to claim 1, wherein the organic protic solvent is a linear or branched C₁ to C₁₀ alkanol.

3. The composition according to claim 2, wherein the concentration of ammonia is from 0.1 to about 8% by weight.

4. The composition according to claim 1, further comprising a second solvent selected from the group consisting of linear, branched and cyclic C₅ to C₁₂ alkanes.

5. The composition according to claim 1, wherein the content of water in the non-aqueous composition is lower than 0.1% by weight.

6. The composition according to claim 1, wherein the non-aqueous composition consists essentially of the organic protic solvent, optionally a C₅ to C₁₂ alkane, the at least one additive of formula I or II, ammonia, and reaction products thereof.

7. The composition according to claim 1, wherein the at least one additive of formula I or II is present in a concentration from 0.005 to 12% by weight.

8. The composition according to claim 1, wherein the at least one additive is a compound of formula I, wherein n is 0, 1 or 2.

9. The composition according to claim 1, wherein R², R⁴, R¹⁰, and R¹² are independently selected from the group consisting of methyl, methoxy, ethyl, ethoxy, propyl, and propoxy.

10. The composition according to claim 1, wherein the additive is selected from the group consisting of trimethoxysilane, triethoxysilane, trimethylsilane, and triethylsilane.

11. A kit comprising
(a) ammonia dissolved in an organic protic solvent, and
(b) at least one additive of formulae I 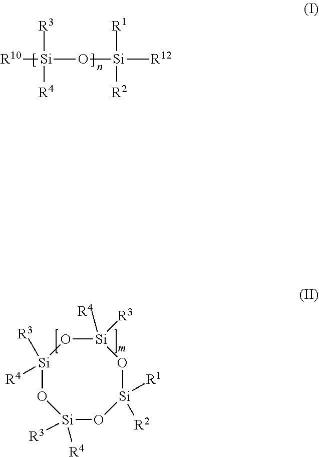
wherein
R¹ is H
R² is selected from the group consisting of H, C₁ to C₁₀ alkyl, C₁ to C₁₀ alkoxy, C₆ to C₁₀ aryl, and C₆ to C₁₀ aroxy,
R³ is selected from the group consisting of R²,
R⁴ is selected from the group consisting of C₁ to C₁₀ alkyl, C₁ to C₁₀ alkoxy, C₆ to C₁₀ aryl, and C₆ to C₁₀ aroxy,
R¹⁰, R¹² are independently selected from the group consisting of C₁ to C₁₀ alkyl and C₁ to C₁₀ alkoxy,
m is 1, 2 or 3, and
n is 0 or an integer from 1 to 100.

12. A method of using the composition according to claim 1, the method comprising using the composition for treating substrates having patterned material layers having line-space dimensions of 50 nm or below, aspect ratios of greater or equal 4, or a combination thereof.

13. A method for manufacturing integrated circuit devices, optical devices, micromachines and mechanical precision devices, the said method comprising the steps of
(1) providing a substrate having patterned material layers having line-space dimensions of 50 nm or below, aspect ratios of greater or equal 4, or a combination thereof,
(2) contacting the substrate at least once with a composition according to claim 1, and
(3) removing the non-aqueous composition from the contact with the substrate.

14. The method according to claim 13, wherein the patterned material layers have line-space dimensions of 32 nm or less and aspect ratios of 10 or more.

15. The method according to claim 13, wherein the patterned material layers are selected from the group consisting of patterned developed photoresist layers, patterned barrier material layers, patterned multi-stack material layers and pattern dielectric material layers.

16. The composition according to claim 1, wherein the organic protic solvent is isopropanol.

17. The composition according to claim 2, wherein the concentration of ammonia is from 0.5 to about 2% by weight.

18. The composition according to claim 1, further comprising a second solvent selected from the group consisting of hexane, heptane, and octane.

19. The composition according to claim 1, wherein the at least one additive of formula I or II is present in a concentration from 0.05 to 10% by weight.

20. The composition according to claim 1, wherein the at least one additive is a compound of formula I, wherein n is 0 or 1.
